(19) United States
(12) Patent Application Publication
(10) Pub. No.: US 2026/0076067 A1
(43) Pub. Date: Mar. 12, 2026

(54) DISPLAY MODULE, METHOD FOR MANUFACTURING THE SAME, AND DISPLAY APPARATUS

(71) Applicants: Tianma Advanced Display Technology Institute (Xiamen) Co., Ltd., Xiamen (CN); Xiamen Tianma Microelectronics Co., Ltd., Xiamen (CN)

(72) Inventors: Yu ZHANG, Xiamen (CN); Bo ZHOU, Xiamen (CN)

(21) Appl. No.: 19/394,853

(22) Filed: Nov. 19, 2025

(30) Foreign Application Priority Data
Nov. 20, 2024 (CN) 202411662648.5

(51) Int. Cl. H10K 59/80; H10K 59/12; H10K 59/122; H10K 59/35; H10K 71/00; H10K 102/00

(52) U.S. Cl. CPC H10K 59/8722; H10K 59/1201; H10K 59/122; H10K 59/352; H10K 59/353; H10K 59/8792; H10K 71/851; H10K 2102/311

(57) ABSTRACT

Provided are a display module, a method for manufacturing the display module, and a display apparatus. The display module includes: a display panel. The display panel includes a display region, a first non-display region located around the display region, a substrate and a first film layer located on a side of the substrate. The first film layer includes an auxiliary sub-portion located in the first non-display region, and the auxiliary sub-portion includes a groove or a protrusion.

### CROSS-REFERENCE TO RELATED APPLICATIONS

The present application claims priority to Chinese Patent Application No. 202411662648.5, filed on Nov. 20, 2024, the content of which is incorporated herein by reference in its entirety.

### TECHNICAL FIELD

The present disclosure relate to the field of display technologies, and in particular, to a display module, a method for manufacturing the display module, and a display apparatus.

### BACKGROUND

Generally, an adhesive layer having a protective function is provided at a lower step of a display panel. However, during the adhesive coating process, the adhesive will flow, and there is a risk of flowing to the display region. After the adhesive flows to the display region, the optical display of the display panel is affected, thereby causing adverse problems.

### SUMMARY

An aspect of the present disclosure provides a display module. The display module includes a display panel. The display panel includes a display region, a first non-display region located around the display region, a substrate and a first film layer located on a side of the substrate. The first film layer includes an auxiliary sub-portion located in the first non-display region, and the auxiliary sub-portion includes a groove or a protrusion.

Another aspect of the present disclosure provides a method for manufacturing a display module. The method includes: forming the display panel. The display panel includes a display region, a first non-display region located around the display region, a substrate and a first film layer located on a side of the substrate. The first film layer includes an auxiliary sub-portion located in the first non-display region, and the auxiliary sub-portion includes a groove or a protrusion.

Another aspect of the present disclosure provides a display apparatus. The display apparatus includes a display module. The display module includes a display panel. The display panel includes a display region, a first non-display region located around the display region, a substrate and a first film layer located on a side of the substrate. The first film layer includes an auxiliary sub-portion located in the first non-display region, and the auxiliary sub-portion includes a groove or a protrusion.

### BRIEF DESCRIPTION OF DRAWINGS

In order to illustrate the technical solutions in the embodiments of the present disclosure or the related art more clearly, the drawings used in the description of the embodiments will be briefly illustrated as follows. It should be noted that, the drawings described below are merely some of, rather than all of the embodiments of the present disclosure. Based on these drawings, those skilled in the art can obtain other drawings.

FIG. 1 is a schematic structural diagram of a display module according to some embodiments of the present disclosure;

FIG. 2 is a structural schematic diagram of a display module according to some embodiments of the present disclosure;

FIG. 3 is a structural schematic diagram of a display module according to some embodiments of the present disclosure;

FIG. 4 is a structural schematic diagram of a display module according to some embodiments of the present disclosure;

FIG. 5 is a structural schematic diagram of a display module according to some embodiments of the present disclosure;

FIG. 6 is a cross-sectional view of a display panel according to some embodiments of the present disclosure;

FIG. 7 is a cross-sectional view of a display panel according to some embodiments of the present disclosure;

FIG. 8 is a top view of a display panel according to some embodiments of the present disclosure;

FIG. 9 is a sectional view along line A1-A2 shown in FIG. 8;

FIG. 10 is a top view of a display panel according to some embodiments of the present disclosure;

FIG. 11 is a sectional view along line B1-B2 shown in FIG. 10;

FIG. 12 is a cross-sectional view along line A1-A2 shown in FIG. 8;

FIG. 13 is a cross-sectional view along line B1-B2 shown in FIG. 10;

FIG. 14 is a top view of a display panel according to some embodiments of the present disclosure;

FIG. 15 is a cross-sectional view of a display panel according to some embodiments of the present disclosure;

FIG. 16 is a top view of a display panel according to some embodiments of the present disclosure;

FIG. 17 is a cross-sectional view of a display panel according to some embodiments of the present disclosure;

FIG. 18 is a top view of a display panel according to some embodiments of the present disclosure;

FIG. 19 is a cross-sectional view of a display panel according to some embodiments of the present disclosure;

FIG. 20 is a cross-sectional view of a display panel according to some embodiments of the present disclosure;

FIG. 21 is a top view of a display panel according to some embodiments of the present disclosure;

FIG. 22 is a top view of a display panel according to some embodiments of the present disclosure;

FIG. 23 is a top view of a display panel according to some embodiments of the present disclosure;

FIG. 24 is a top view of the display panel according to some embodiments of the present disclosure;

FIG. 25 is a process flow diagram of a display module according to some embodiments of the present disclosure;

FIG. 26 is a top view of a display panel according to some embodiments of the present disclosure;

FIG. 27 is a top view of a display panel according to some embodiments of the present disclosure; and

FIG. 28 is a schematic structural diagram of a display apparatus according to some embodiments of the present disclosure.

### DESCRIPTION OF EMBODIMENTS

In order to better understand technical solutions of the present disclosure, embodiments of the present disclosure are described in detail below in conjunction with the drawings.

It should be noted that, the described embodiments are only some rather than all of the embodiments of the present disclosure. All other embodiments obtained by those skilled in the art without creative efforts according to some embodiments of the present disclosure are within the protection scope of the present disclosure.

Terms used in the embodiments of the present disclosure are merely for the purpose of describing specific embodiments, but not intended to limit the present disclosure. Singular forms of “a/an”, “the” and “said” used in the embodiments of the present disclosure and the appended claims are also intended to include plural forms, unless clearly indicating others.

It should be understood that the term “and/or” used herein is merely an association relationship describing an associated object, and indicates that there may be three relationships, for example, A and/or B, and may indicate: there are three cases: A alone, A and B together, and B alone. In addition, the character “/” herein generally indicates that the related objects before and after the character present an “or”relationship.

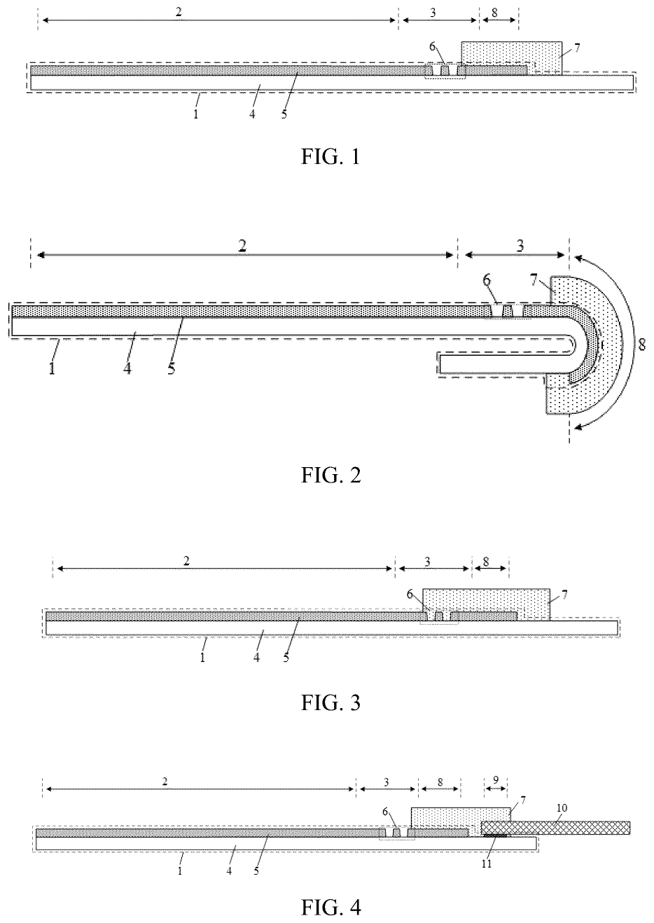

The present disclosure provides a display module. FIG. 1 is a schematic structural diagram of a display module according to some embodiments of the present disclosure, and FIG. 2 is a schematic structural diagram of another display module according to some embodiments of the present disclosure. As shown in FIG. 1 and FIG. 2, the display module includes a display panel 1, and the display panel 1 may be of various types such as a Light Emitting Diode (LED) display panel, and an Organic Light Emitting Diode (OLED) display panel.

The display panel 1 includes a display region 2 and a first non-display region 3 located around the display region 2. The display panel 1 further includes a substrate 4 and a first film layer 5 located on a side of the substrate 4. The first film layer 5 includes an auxiliary sub-portion 6 that is located in the first non-display region 3, and the auxiliary sub-portion 6 includes a groove or a protrusion.

In some embodiment of the present disclosure, the auxiliary sub-portion 6 is located around the display region 2 and includes a groove or a protrusion. When a material having a certain fluidity is coated around the display region 2, when the material flows to the auxiliary sub-portion 6, filling occurs in the groove or filling occurs in the gap between the protrusions, thereby slowing the fluidity. In some embodiments of the present disclosure, when an adhesive layer 7 needs to be provided above the display panel 1, after coating the adhesive, the auxiliary sub-portion 6 can block the adhesive from flowing toward the display region 2, thereby preventing the adhesive from flowing into the display region 2 and affecting normal optical display. In other words, since the auxiliary sub-portion 6 can be effectively used to prevent the adhesive from flowing to the display region 2, the coating thickness of the adhesive can be designed to be larger, so as to form a thick adhesive layer 7 and to improve the protection performance of the adhesive layer 7.

The embodiments of the present disclosure can be applied in transparent display.

In the non-transparent display, the display module further includes a polarizer, and the polarizer is located on a side of the display panel 1 and at least located in the display region 2. The non-transparent display uses the polarizer to block the flow of the adhesive. The adhesive flows to one side of the polarizer and is blocked by the polarizer, so that the adhesive does not further flow to the display region 2. In some embodiments of the present disclosure, the thickness of the existing polarizer is 100 μm to 150 μm. When the adhesive layer 7 of 100 μm is formed, the polarizer can block the adhesive and prevent the adhesive from flowing over the polarizer to the display region 2.

However, in the field of transparent display, in order to improve the transmittance, a polarizer is usually no longer provided. In the related art, in order to prevent the adhesive from flowing to the display region 2, the distance between the adhesive coating area and the display region 2 is usually increased. In some embodiments of the present disclosure, the width of the part of the non-display region between the adhesive coating area and the display region 2 is increased to reserve enough leveling space for the adhesive, but this will lead to an increase in the frame width, which is not conducive to realizing a narrow frame design. If the frame is to be optimized, only the width of the adhesive coating area can be compressed, but this will lead to a decrease in the protection performance of the adhesive layer 7.

After adopting the technical solution according to some embodiments of the present disclosure, even without a polarizer, the auxiliary sub-portion 6 can be used to effectively prevent the adhesive from flowing to the display region 2. Therefore, there is no need to increase the distance between the adhesive coating area and the display region 2, and the purposes of narrowing the frame and improving the protection performance of the adhesive layer 7 are achieved simultaneously.

In some embodiments of the present disclosure, referring to FIG. 1 and FIG. 2 again, the display module further includes an adhesive layer 7, and the adhesive layer 7 is located on a side of the substrate 4 facing the first film layer 5 and at least located in the first non-display region 3.

The adhesive layer 7 may include an ultraviolet light-curable adhesive material, which is used to provide protection and prevent dust, moisture, oxygen, and the like from causing damage to circuits and the like. In the forming process, a layer of adhesive is first coated and then cured to form the adhesive layer 7. As described above, after coating the adhesive, when the adhesive flows to the auxiliary sub-portion 6, filling occurs in the groove or in the gaps between the protrusions, thereby slowing the fluidity thereof and preventing it from further flowing to the display region 2.

FIG. 3 is a structural schematic diagram of a display module according to some embodiments of the present disclosure. In some embodiments of the present disclosure, as shown in FIG. 3, at least part of the adhesive layer 7 overlaps with the auxiliary sub-portion 6. That is, a part of the adhesive is filled in the groove of the auxiliary sub-portion 6 or filled in the gap between the protrusions of the auxiliary sub-portion 6 during the flowing process, thereby reducing the fluidity of the adhesive.

In addition, when a groove is formed in the first film layer 5, if the groove penetrates the first film layer 5, some metal traces below the first film layer 5 may be exposed. The adhesive filled in the groove can encapsulate the exposed metal traces of the groove, thereby preventing the exposed metal traces from being eroded by water and oxygen.

In some embodiments of the present disclosure, referring to FIG. 1 and FIG. 2, the display panel 1 further includes a bending region 8, and at least part of the adhesive layer 7 is located in the bending region 8. In such structure, the adhesive layer 7 serves as a bending protection layer. When the bending region 8 is bent during the manufacturing process of the display module, the adhesive layer 7 can disperse and absorb the stress generated during bending, thereby avoiding the traces breakage caused by stress concentration.

The auxiliary sub-portion 6 is located between the display region 2 and the bending region 8. On the one hand, the auxiliary sub-portion 6 can effectively block the adhesive in the bending region 8 from flowing to the display region 2. On the other hand, the groove or the protrusion of the auxiliary sub-portion 6 does not affect the overall thickness of the adhesive layer 7 in the bending region 8 too much, so that the thickness of the adhesive layer 7 in the bending region 8 is more uniform, and the stress can be better balanced during bending.

In some embodiments of the present disclosure, referring to FIG. 1, the first non-display region 3 may be the part of the non-display region located between the display region 2 and the bending region 8. In this case, the first non-display region 3 may be understood as the lower frame of the display panel 1, and the auxiliary sub-portion 6 is located in the first non-display region 3, that is, located between the display region 2 and the bending region 8. Alternatively, the first non-display region 3 may also include a bending region 8. In this case, the first non-display region 3 may be understood as a lower step region, and the auxiliary sub-portion 6 is located in the portion of the first non-display region 3 between the display region 2 and the bending region 8.

In some embodiments of the present disclosure, at least part of the auxiliary sub-portion 6 may also be located in the bending region 8, so as to compress the width of the space occupied by the auxiliary sub-portion 6 between the bending region 8 and the display region 2, which is beneficial to realizing an ultra-narrow frame or frameless design.

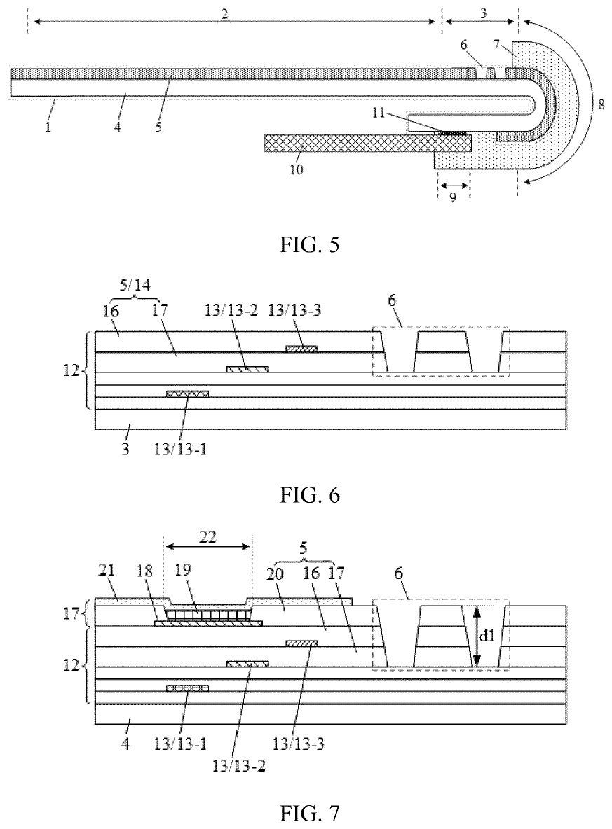

FIG. 4 is a structural schematic diagram of a display module according to some embodiments of the present disclosure, and FIG. 5 is a structural schematic diagram of a display module according to some embodiments of the present disclosure. In some embodiments of the present disclosure, as shown in FIG. 4 and FIG. 5, the display panel 1 further includes a binding region 9 that is located on the back side of the display panel 1. In an example, the bending region 8 is located between the display region 2 and the binding region 9. When the bending region 8 is bent, the binding region 9 is driven to be placed on the back side of the display panel 1.

The display module further includes a circuit board 10 bonded and connected to the display panel 1 in the binding region 9. In an example, the binding region 9 includes a pad 11, and the pad is electrically connected to various signal lines in the display panel 1. The circuit board 10 is electrically connected to the pad 11.

The adhesive layer 7 further at least covers a part of the circuit board 10 located in the binding region 9. That is, during the manufacturing process of the display module, the circuit board 10 is bonded first, and then coating the adhesive to form the adhesive layer 7, so as to realize the coverage of the adhesive layer 7 on the bonded part of the circuit board 10.

The adhesive layer 7 encapsulates and protects the bonded part of the circuit board 10. On one hand, after the adhesive is cured, various elements, such as chips and pins, of the bonded part of the circuit board 10 can be firmly fixed at corresponding positions, so as to prevent them from loosening or displacing due to external mechanical action, thereby ensuring the stable electrical connection between the circuit board 10 and the display panel 1. On the other hand, when subjected to external impact, the adhesive layer 7 may also absorb a part of the impact force, thereby reducing direct damage by the external force to the bonded part of the circuit board 10. Further, the adhesive layer 7 has good sealing performance after being cured, which can effectively prevent external moisture and dust from entering, and prevent adverse problems such as abnormal connection of the bonded part of the circuit board 10.

In addition, after adopting the technical solution provided by the embodiments of the present disclosure, since the auxiliary sub-portion 6 in the first film layer 5 can be used to slow the flow of the adhesive, under the condition of ensuring that the adhesive does not flow to the display region 2, the adhesive layer 7 can be set to be thick to a certain extent, thereby providing stronger encapsulation protection for traces in the binding region 9.

FIG. 6 is a cross-sectional view of a display panel 1 according to some embodiments of the present disclosure. In some embodiments of the present disclosure, as shown in FIG. 6, the display panel 1 includes an array layer 12, and the array layer 12 includes a metal layer 13. A part of the metal layer 13 includes a planarization layer 14 on a side adjacent to and/or away from the substrate 4, and the first film layer 5 includes at least one planarization layer 14.

In some embodiments of the present disclosure, the display panel 1 includes a first metal layer 13-1, a second metal layer 13-2 located on a side of the first metal layer 13-1 away from the substrate 4, and a third metal layer 13-3 located on a side of the second metal layer 13-2 away from the substrate 4. The planarization layer 14 includes a first planarization layer 15 and a second planarization layer 16. The first planarization layer 15 is located between the second metal layer 13-2 and the third metal layer 13-3, and the second planarization layer 16 is located on a side of the third metal layer 13-3 away from the substrate 4. The first film layer 5 may include a first planarization layer 15 and/or a second planarization layer 16.

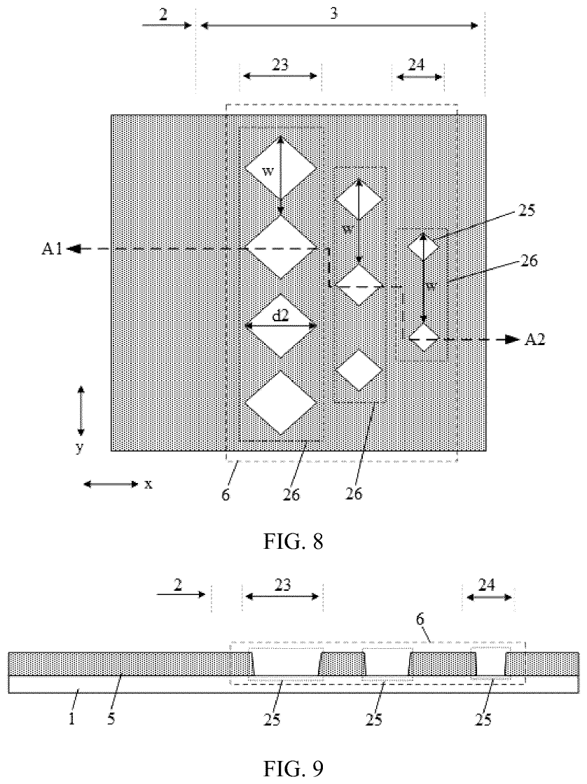

FIG. 7 is a cross-sectional view of the display panel 1 according to some embodiments of the present disclosure. As shown in FIG. 7, the display panel 1 includes a light-emitting device layer 17, and the light-emitting device layer includes an anode 18, a light-emitting layer 19, a pixel definition layer 20, and a cathode 21. The pixel definition layer 20 includes a first opening 22 that exposes the anode 18. The light-emitting layer 19 is located in the first opening 22, and the first film layer 5 includes the pixel definition layer 20.

Both the planarization layer 14 and the pixel definition layer 20 are organic film layers. The existing original organic film layer in the display panel 1 is reused as the first film layer 5. First, there is no need to additionally form other film layers as the first film layer 5. Second, the organic film layers have a relatively large thickness, so when the groove is formed inside the organic film layers, the groove can have a greater depth, and can be filled with a larger volume of adhesive, thereby playing a greater role in reducing the flow of the adhesive.

In some embodiments of the present disclosure, with reference to FIG. 8 to FIG. 11, the first non-display region 3 includes a first region 23 and a second region 24, and the first region 23 is located between the display region 2 and the second region 24.

The auxiliary sub-portion 6 includes a plurality of first sub-portions 25, and the first sub-portion 25 may be a groove. The density of the first sub-portion 25 in the first region 23 and the second region 24 is different, and/or the volume of the first sub-portion 25 in the first region 23 and the second region 24 is different.

In a more concrete structure, the auxiliary sub-portion 6 includes at least two sub-portion units 26 arranged along a first direction x, and the first direction x is parallel to the arrangement direction of the display region 2 and the first non-display region 3. The sub-portion unit 26 includes a plurality of first sub-portions 25 arranged along a second direction y, and the second direction y intersects with the first direction x.

In the first region 23 and the second region 24, the spacing between adjacent first sub-portions 25 in the sub-portion unit 26 is different, that is, the density of the first sub-portions 25 is different. Additionally/alternatively, in the first region 23 and the second region 24, the volume of the first sub-portions 25 in the sub-portion unit 26 is different.

The greater the arrangement density and/or volume of the first sub-portions 25, the more the adhesive will be filled in the first sub-portions 25 when flowing to the area where the first sub-portions 25 are located, and the greater the degree of reduction in the fluidity. In some embodiments of the present disclosure, by performing differentiated design of the arrangement density and/or volume of the first sub-portions 25 in different regions, the first sub-portions 25 at different positions may have different degrees of influence on the flow of the adhesive, thereby achieving different purposes in a targeted manner. For details, please refer to the subsequent embodiments.

FIG. 8 is a top view of the display panel 1 according to some embodiments of the present disclosure, and FIG. 9 is a sectional view along a direction A1-A2 shown in FIG. 8. When performing the differentiated design of the first sub-portions 25, in some embodiments of the present disclosure, as shown in FIG. 8 and FIG. 9, the density of the first sub-portions 25 in the second region 24 is less than the density of the first sub-portions 25 in the first region 23, and/or the volume of the first sub-portions 25 in the second region 24 is less than the volume of the first sub-portions 25 in the first region 23.

In some embodiments of the present disclosure, the spacing between adjacent first sub-portions 25 in the sub-portion unit 26 of the second region 24 is greater than the spacing between adjacent first sub-portions 25 in the sub-portion unit 26 of the first region 23, and/or the volume of the first sub-portion 25 in the sub-portion unit 26 of the second region 24 is less than the volume of the first sub-portion 25 in the sub-portion unit 26 of the first region 23.

In such arrangement manner, the density of the first sub-portions 25 in the region farther away from the display region 2 is set to be more sparsely, and/or the volume is set to be smaller. The density of the first sub-portions 25 in the region closer to the display region 2 is set to be denser, and/or the volume is set to be larger.

Such arrangement can first block the flow of the adhesive to a small extent at the position away from the display region 2, and the closer to the display area 2, the greater the degree of blocking. In this way, the height of the adhesive can be smoothly reduced. That is, along the direction adjacent to the display region 2, the distance between the upper surface of the adhesive layer 7 away from the substrate 4 and the substrate 4 decreases smoothly, for example, smoothly transitioning from 100 μm to 0, so that the structural characteristics of the adhesive layer 7 are better. In addition, at the position adjacent to the display region 2, the first sub-portions 25 have a strong blocking effect on the adhesive, which can still effectively prevent the adhesive from further flowing to the display region 2.

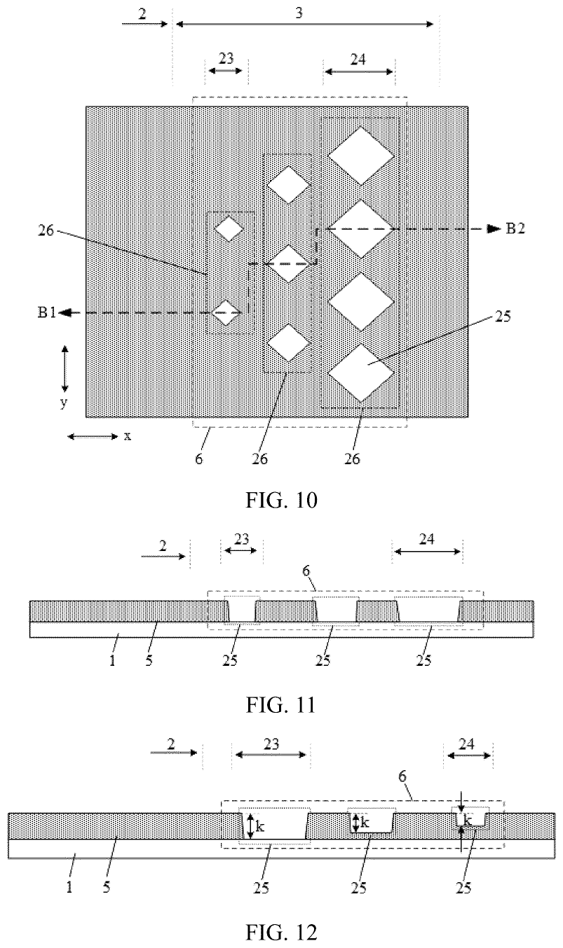

FIG. 10 is a top view of the display panel 1 according to some embodiments of the present disclosure, and FIG. 11 is a sectional view along a direction B1-B2 shown in FIG. 10. When performing the differentiated design of the first sub-portion 25, in some embodiments of the present disclosure, as shown in FIG. 10 and FIG. 11, the density of the first sub-portions 25 in the second region 24 is greater than the density of the first sub-portions 25 in the first region 23, and/or the volume of the first sub-portions 25 in the second region 24 is greater than the volume of the first sub-portions 25 in the first region 23.

In some embodiments of the present disclosure, the spacing between adjacent first sub-portions 25 in the sub-portion unit 26 of the second region 24 is less than the spacing between adjacent first sub-portions 25 in the sub-portion unit 26 of the first region 23, and/or the volume of the first sub-portions 25 in the sub-portion unit 26 of the second region 24 is greater than the volume of the first sub-portions 25 in the sub-portion unit 26 of the first region 23.

In such arrangement manner, the density of the first sub-portions 25 in the region farther away from the display region 2 is set be denser, and/or the volume is set to be larger. The density of the first sub-portions 25 in the region closer to the display region 2 is set to be sparser, and/or the volume is set to be smaller.

Such arrangement can enable the adhesive to be filled in the first sub-portion 25 to a greater extent when the adhesive starts to flow toward the display region 2, thereby reducing the fluidity to a greater extent, which can reduce the risk of the adhesive flowing to the display region 2 to a greater extent.

In some embodiments of the present disclosure, referring to FIG. 8 to FIG. 11, the areas of the orthographic projections of the first sub-portions 25 in the first region 23 and the second region 24 in a direction of the plane of the display module are different. The area of the orthographic projection of the first sub-portions 25 may be defined by the orthographic projection of the edge of the first sub-portion 25.

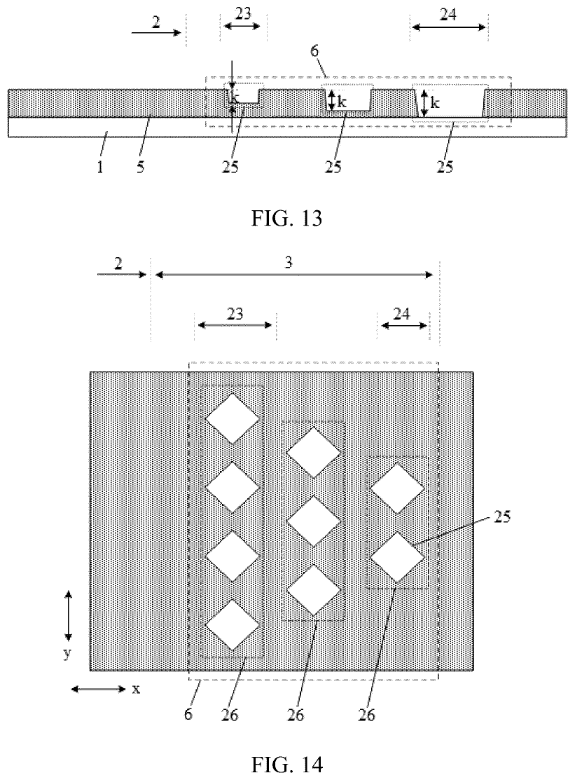

FIG. 12 is a cross-sectional view along a direction A1-A2 shown in FIG. 8, and FIG. 13 is a cross-sectional view along a direction B1-B2 shown in FIG. 10. As shown in FIG. 12 and FIG. 13, in a direction perpendicular to the plane of the display module, the heights of the first sub-portions 25 in the first region 23 and the second region 24 are different. In some embodiments of the present disclosure, some of the first sub-portions 25 do not penetrate the first film layer 5 and have a smaller height, and some of the first sub-portions 25 penetrate the first film layer 5 and have a larger height. In FIG. 12 and FIG. 13, the height of the first sub-portion 25 is represented by k, and values of k corresponding to at least different first sub-portions 25 are different.

Such design can realize the differentiated design of the volume of different first sub-portions 25. Different volumes of the first sub-portions 25 result in different degrees of blocking of the flow of the adhesive, thereby achieving the purpose of smoothly decreasing the height of the adhesive layer 7, or slowing the fluidity of the adhesive to a greater extent when the adhesive starts to flow toward the display region 2.

In some embodiments of the present disclosure, referring to FIG. 8 and FIG. 10, along the direction from the first non-display region 3 toward the display region 2, the density of the first sub-portions 25 gradually changes and/or the volume of the first sub-portions 25 gradually changes, so that the degree of blocking of the adhesive flow by the first sub-portions 25 gradually changes, achieving a relatively smooth transition.

In an example, along the direction from the first non-display region 3 toward the display region 2, the spacing between adjacent first sub-portions 25 in at least two sub-portion units 26 decreases, and/or the volume of the first sub-portions 25 in the sub-portion unit 26 increases. Alternatively, along the direction from the first non-display region 3 toward the display region 2, the spacing between adjacent first sub-portions 25 in the at least two sub-portion units 26 increases, and/or the volume of the first sub-portions 25 in the sub-portion unit 26 decreases.

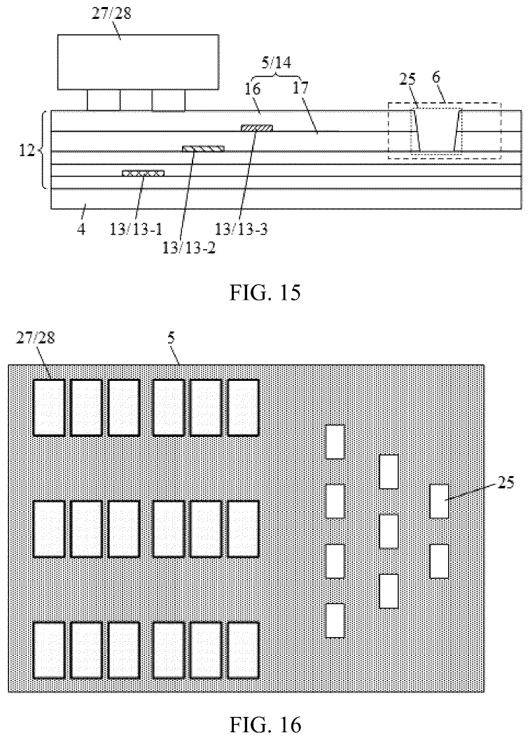

FIG. 14, which is a top view of the display panel 1 according to some embodiments of the present disclosure. In should be understood that, in some embodiments of the present disclosure, in order to simplify the design, as shown in FIG. 14, the density and the volume of the first sub-portions 25 in the first region 23 and the second region 24 may be the same.

In some embodiments of the present disclosure, referring to FIG. 8 and FIG. 10, the auxiliary sub-portion 6 includes at least two sub-portion units 26 arranged along the first direction x, and the first direction x is parallel to the arrangement direction of the display region 2 and the first non-display region 3. The sub-portion unit 26 includes a plurality of first sub-portions 25 arranged along the second direction y, and the second direction y intersects with the first direction x.

For two adjacent sub-portion units 26, along the first direction x, the spacing between the first sub-portion 25 in one sub-portion unit 26 and an adjacent first sub-portion 25 in the other sub-portion unit 26 overlaps.

Compared with the arrangement in which the plurality of first sub-portions 25 are arranged in a row-column matrix, in such arrangement manner, when the adhesive flows through the gap between adjacent first sub-portions 25 in a certain sub-portion unit 26 and further flows toward the display region 2, the adhesive passes through the first sub-portion 25 in the adjacent sub-portion unit 26, and is filled in the first sub-portion 25, so that the flowing speed of the adhesive in the first sub-portion 25 is reduced. Such design can improve the effect of the first sub-portions 25 in slowing the flow of the adhesive.

In some embodiments of the present disclosure, in at least some of the sub-portion unit 26, along the second direction y, a sum of a length of one first sub-portion 25 and a distance between the one first sub-portion 25 and its adjacent first sub-portion 25 is greater than or equal to 10 μm and less than or equal to 30 μm. Referring to FIG. 8, the sum of the length of one first sub-portion 25 and a distance between the one first sub-portion 25 and its adjacent first sub-portion 25 is denoted by w, and w corresponding to different sub-portion units 26 may be the same or may be different.

Designing the minimum value of the above distance as 10 μm can prevent the arrangement of the first sub-portions 25 from being too dense, which would result in excessive exposure of the metal traces of the first sub-portions 25 and increase the risk of the metal traces being eroded by water and oxygen. Designing the maximum value of the above distance as 30 μm can prevent the arrangement of the first sub-portions 25 from being too sparse, which can ensure that the first sub-portions 25 can have a sufficient slowing effect on the flow of the adhesive.

In some embodiments of the present disclosure, referring to FIG. 15 to FIG. 18, the display panel 1 includes pixels 27. The auxiliary sub-portion 6 includes a plurality of first sub-portions 25, and in a direction perpendicular to the plane of the display module, the shape of the projection of the first sub-portions 25 is the same as the shape of the pixels 27.

In some embodiments of the present disclosure, the pixel 27 may be understood as a light-emitting device.

FIG. 15 is a cross-sectional view of a display panel 1 according to some embodiments of the present disclosure, and FIG. 16 is a top view of the display panel 1 according to some embodiments of the present disclosure. In some embodiments of the present disclosure, as shown in FIG. 15 and FIG. 16, in the display panel 1, the display panel 1 includes an array layer 12 and a LED device 28 located on a side of the array layer 12, and the pixel 27 refers to the LED device 28. The expression “the shape of the projection of the first sub-portions 25 is the same as the shape of the pixels 27” can be understood as the shape of the projection of the first sub-portions 25 is the same as the shape of the LED devices 28. In such structure, the shape of the projection of the LED device 28 and the first sub-portion 25 may be square or the like.

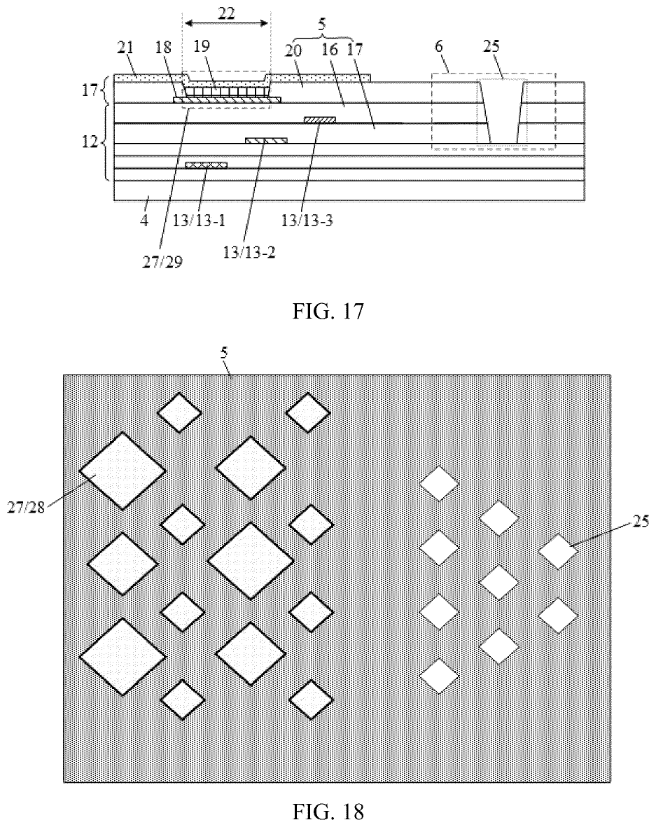

FIG. 17 is a cross-sectional view of a display panel 1 according to some embodiments of the present disclosure, and FIG. 18 is a top view of the display panel 1 according to some embodiments of the present disclosure. As shown in FIG. 17 and FIG. 18, in the display panel 1, the display panel 1 includes an array layer 12 and a light-emitting device layer located on a side of the array layer 12. The light-emitting device layer includes an OLED device 29, and the OLED device 29 include an anode 18, a light-emitting layer 19, and a cathode 21. The pixel 27 refers to the OLED device 29. The shape of the OLED device 29 is specifically defined by the first opening 22 of the pixel definition layer 20. The expression “the shape of the projection of the first sub-portions 25 is the same as the shape of the pixels 27” can be understood as the shape of the projection of the first sub-portions 25 is the same as the shape of the first opening 22 of the pixel definition layer 20. In such structure, the shape of the projection of the OLED device 29 and the first sub-portion 25 may be square, rhombic, circular, elliptical, and the like.

Designing the shape of the first sub-portions 25 to be the same as the shape of the pixels 27 can homogenize the panel structure, weaken the difference between the film layer structure at the position of the first sub-portion 25 and the film layer structure at other positions, and reduce the visibility of the first sub-portions 25.

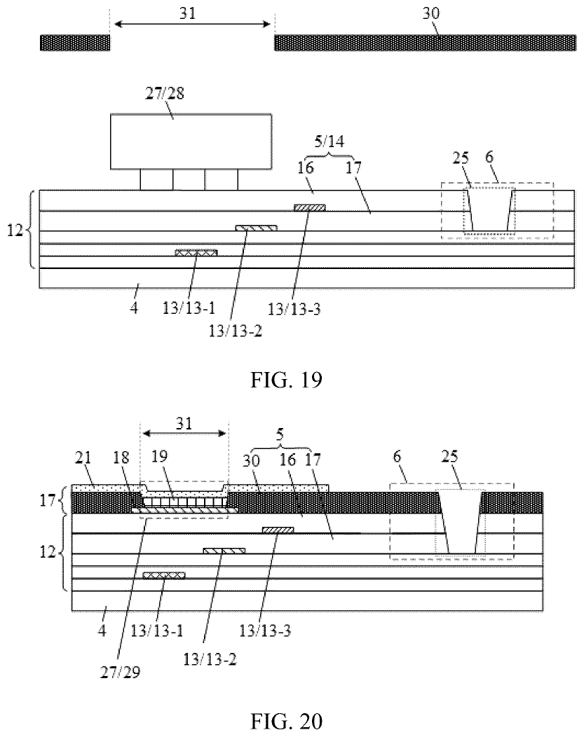

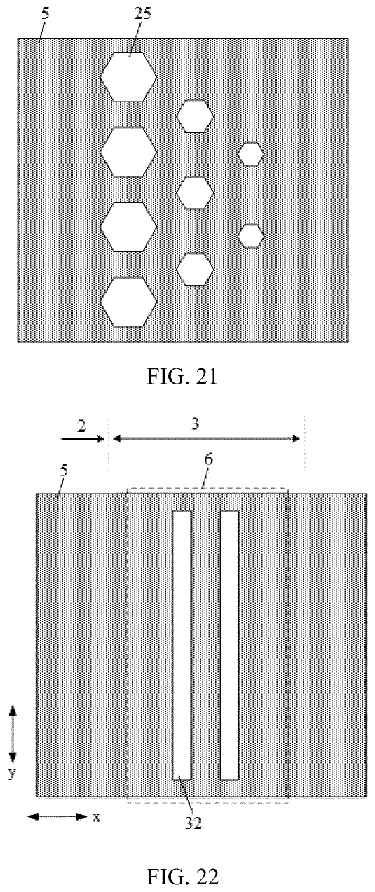

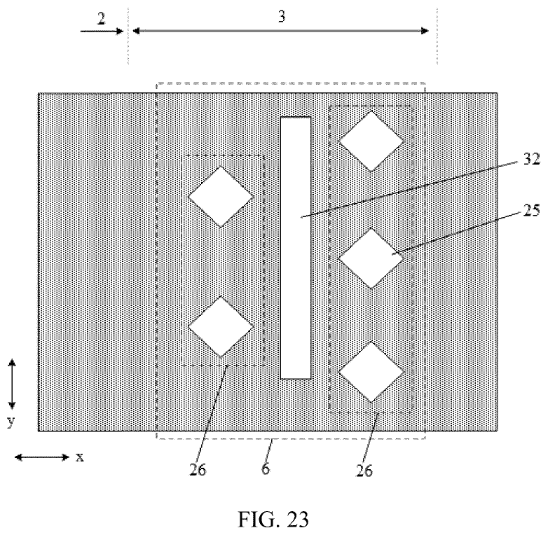

In some embodiments of the present disclosure, referring to FIG. 19 and FIG. 20, the display panel 1 includes a light-shielding layer 30, and the light-shielding layer 30 includes a second opening 31.

The auxiliary sub-portion 6 includes a plurality of first sub-portions 25, and in a direction perpendicular to the plane of the display module, the shape of the projection of the first sub-portions 25 is the same as the shape of the second opening 31.

FIG. 19 is a cross-sectional view of a display panel 1 according to some embodiments of the present disclosure. In some embodiments of the present disclosure, as shown in FIG. 19, in the display panel 1, the display panel 1 includes an array layer 12 located on a side of a substrate 4 and a LED device 28 located on a side of the array layer 12. The light-shielding layer 30 is located on a side of the LED device 28 away from the substrate 4, and the shape of the second opening 31 of the light-shielding layer 30 is the same as the shape of the LED device 28.

FIG. 20 is a cross-sectional view of a display panel 1 according to some embodiments of the present disclosure. As shown in FIG. 20, in the display panel 1, the display panel 1 includes an array layer 12 and a light-emitting device layer located on a side of the array layer 12. The light-emitting device layer includes an OLED device 29 and a light-shielding layer 30. The OLED device 29 includes an anode 18, a light-emitting layer 19 and a cathode 21, and the light-shielding layer 30 includes a second opening 31. The second opening 31 exposes at least a part of the anode 18, and the light-emitting layer 19 is located in the second opening 31.

The shape of the first sub-portion 25 is the same as the shape of the opening of the light-shielding layer 30, which can also homogenize the panel structure, weaken the difference between the film layer structure at the position of the first sub-portion 25 and the film layer structure at other positions, and reduce the visibility of the first sub-portions 25.

In some embodiments of the present disclosure, the first sub-portion 25 may also be of other shapes, such as polygons including pentagons, hexagons, octagons, and the like. FIG. 21, which is a top view of the display panel 1 according to some embodiments of the present disclosure. In some embodiments of the present disclosure, as shown in FIG. 21, in a direction perpendicular to the plane of the display module, the shape of the projection of the first sub-portion 25 is hexagonal.

In some embodiments of the present disclosure, as shown in FIG. 22, which is a top view of the display panel 1 according to some embodiments of the present disclosure, the auxiliary sub-portion 6 includes a strip-shaped second sub-portion 32, and the extending direction of the second sub-portion 32 intersects with the arrangement direction of the display region 2 and the first non-display region 3. In an example, the display region 2 and the first non-display region 3 are arranged along the first direction x, and the second sub-portion 32 extends along the second direction y.

The second sub-portion 32 is a strip-shaped structure. When the adhesive flows to the second sub-portion 32, a greater degree of filling occurs in the second sub-portion 32, and the fluidity thereof is slower, thereby preventing the adhesive flow from flowing to the display region 2 to a greater extent. Such design is more suitable for structures with a thick adhesive layer 7. A thick adhesive layer 7 means that the coated adhesive is thick and the flow of the adhesive is greater, and then the flow of the adhesive can be effectively slowed using the adjusted second sub-portion 32.

FIG. 23, which is a top view of the display panel 1 according to some embodiments of the present disclosure. In some embodiments of the present disclosure, as shown in FIG. 23, the auxiliary sub-portion 6 includes a plurality of first sub-portions 25 arranged in an array and a strip-shaped second sub-portion 32. The extending direction of the second sub-portion 32 intersects with the arrangement direction of the display region 2 and the first non-display region 3, and the second sub-portion 32 is located between at least some of adjacent first sub-portions 25.

In an example, the plurality of first sub-portions 25 may be arranged in a triangular array or in a row-column array. In some embodiments of the present disclosure, the auxiliary sub-portion 6 includes at least two sub-portion units 26 arranged along the first direction x, and the first direction x is parallel to the arrangement direction of the display region 2 and the first non-display region 3. The sub-portion unit 26 includes a plurality of first sub-portions 25 arranged along the second direction y. The second sub-portion 32 is located between at least some adjacent sub-portion units 26, and the second sub-portion 32 extends along the second direction y.

With the design of the first sub-portion 25 and the second sub-portion 32, the degree of filling of the first sub-portion 25 by the adhesive is slightly smaller, the degree of filling of the second sub-portion 32 by the adhesive is slightly larger. With the arrangement of the first sub-portion 25 and the second sub-portion 32, the second sub-portion 32 is spaced between at least some of the adjacent first sub-portions 25, which can produce sufficient and gradually slow down effect on the flow of the adhesive, so that the thickness of the adhesive can be smoothly reduced toward the display region 2.

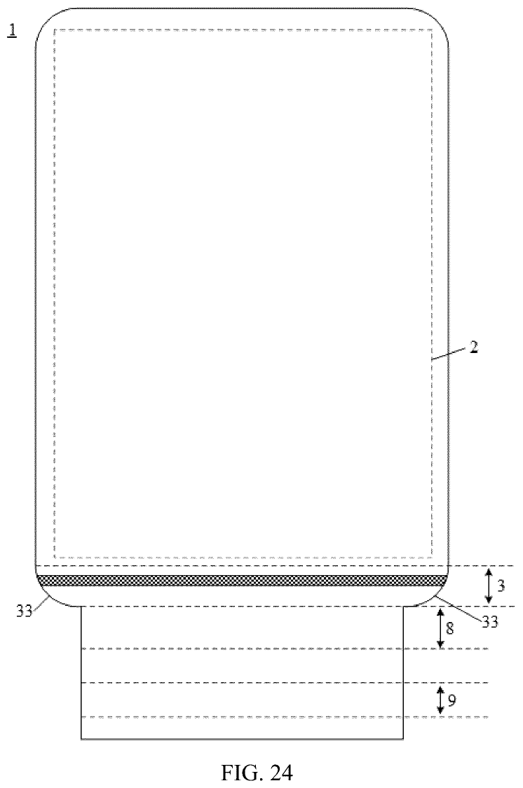

FIG. 24, which is a top view of the display panel 1 according to some embodiments of the present disclosure. In some embodiments of the present disclosure, as shown in FIG. 24, the first non-display region 3 includes two first edges 33 that are opposite. The arrangement direction of the two first edges 33 intersects with the arrangement direction of the display region 2 and the first non-display region 3. The first edges 33 are arc-shaped edges, which may also be understood as edges with R-angle. The first edge 33 exposes an end portion of the second sub-portion 32.

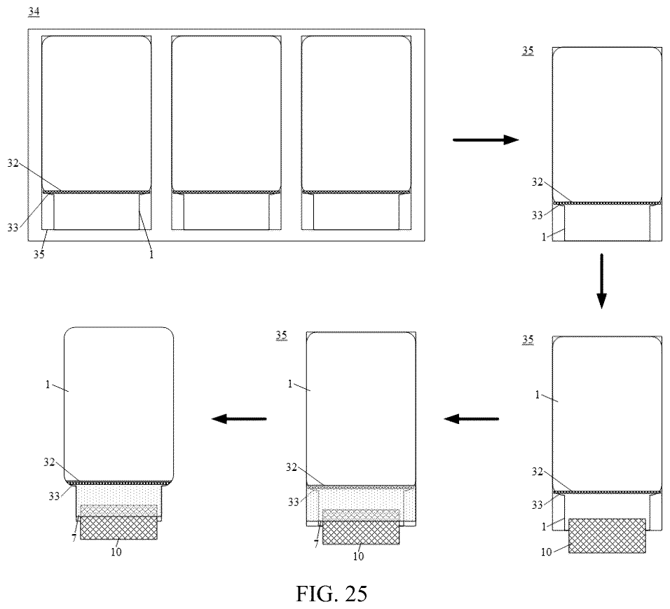

FIG. 25, which is a process flow diagram of a display module according to some embodiments of the present disclosure. In a manufacturing process of the display module, as shown in FIG. 25, a motherboard 34 is first formed. The motherboard 34 includes a plurality of to-be-cut panels 35, and each to-be-cut panel 35 includes one display panel 1. A blank region is provided between the edge of the to-be-cut panel 35 and the first edge 33 of the display panel 1, and an end portion of the second sub-portion 32 in the display panel 1 extends into the blank region.

After cutting the motherboard 34, a plurality of independent to-be-cut panels 35 are formed. Then, the circuit board 10 is bonded, and then the to-be-cut panels 35 are coated with adhesive to form the adhesive layer 7. After coating the adhesive, when the adhesive flows to the second sub-portion 32, the adhesive fills in the second sub-portion 32, and then overflows to the blank regions on both sides along the extending direction of the second sub-portion 32, resulting in accumulation in the blank regions. After the adhesive is cured, the to-be-cut panel 35 is further cut along the edge of the display panel 1. The adhesive accumulated in the blank region is cut away along with the blank region, thereby preventing the accumulated adhesive from remaining in the display panel 1 and thus affecting the panel structure. Such technical solution is more suitable for panel structures with a thick adhesive layer 7. When the thick adhesive is coated, it can prevent the adhesive from accumulating inside the panel during the flowing process and affecting the panel structure.

In some embodiments of the present disclosure, to enable the auxiliary sub-portion 6 to have a sufficient slowing effect on the flow of the adhesive, referring to FIG. 7, in the direction perpendicular to the plane of the display module, the height of the groove or the protrusion is d1, where 1 μm≤d1≤10 μm. In an example, the height of the first sub-portion 25 is greater than or equal to 1 μm and less than or equal to 10 μm, and the height of the second sub-portion 32 is greater than or equal to 1 μm and less than or equal to 10 μm. The values of d1 corresponding to different grooves (or protrusions) may be the same or different.

Additionally/alternatively, to enable the auxiliary sub-portion 6 to have a sufficient slowing effect on the flow of the adhesive, referring to FIG. 8, along the arrangement direction of the display region 2 and the first non-display region 3, the length of the groove or the protrusion is d2, where 5 μm≤d2≤30 μm. In an example, along the first direction x, the length of the first sub-portion 25 is greater than or equal to 5 μm and less than or equal to 30 μm, and the length of the second sub-portion 32 is greater than or equal to 5 μm and less than or equal to 30 μm. The values of d2 corresponding to different grooves (or protrusions) may be the same or different.

Additionally/alternatively, to enable the auxiliary sub-portion 6 to have a sufficient slowing effect on the flow of the adhesive, along the arrangement direction of the display region 2 and the first non-display region 3, the length of the auxiliary sub-portion 6 is p, where 30 μm≤p≤150 μm.

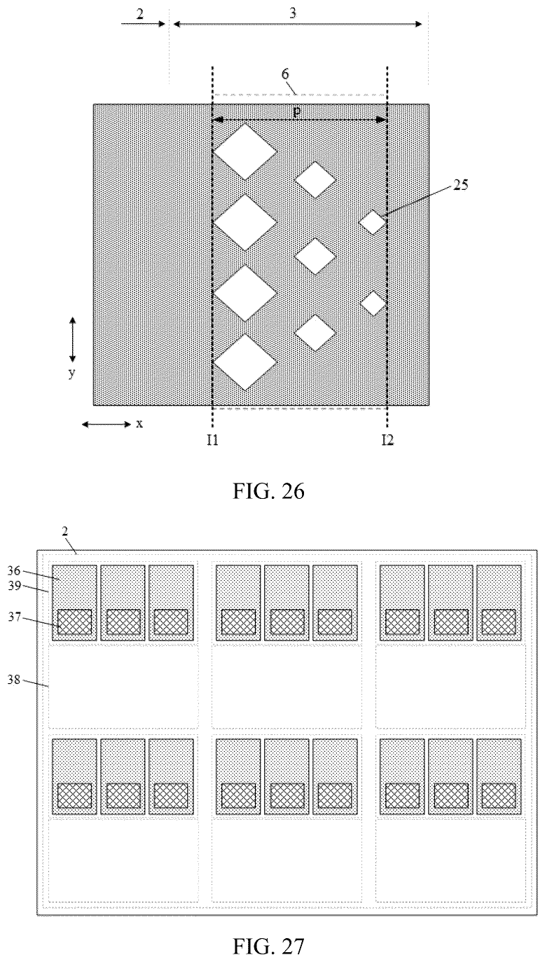

FIG. 26, which is a top view of the display panel 1 according to some embodiments of the present disclosure. As shown in FIG. 26, the length of the auxiliary sub-portion 6 may be defined according to the following manner: the first film layer 5 has a virtual first straight line I1 and a virtual second straight line I2 that both extend along the second direction y. The virtual first straight line I1 is located on a side of the plurality of grooves in the auxiliary sub-portion 6 adjacent to the display region 2 and is tangent to the groove (or protrusion) closest to the display region 2. The virtual second straight line I2 is located on a side of the plurality of grooves in the auxiliary sub-portion 6 away from the display region 2 and is tangent to the groove (or protrusion) farthest from the display region 2. The length of the auxiliary sub-portion 6 in the first direction x may be defined by the distance between the virtual first straight line I1 and the virtual second straight line I2.

FIG. 27, which is a top view of the display panel 1 according to some embodiments of the present disclosure. In some embodiments of the present disclosure, as shown in FIG. 27, the display panel 1 further includes a pixel circuit 36 and a light-emitting element 37, and the light-emitting element 37 may be a micro LED or another type of light-emitting device. The display region 2 includes a light-transmitting region 38 and a non-light-transmitting region 39, and the pixel circuit 36 and the light-emitting element 37 are located in the non-light-transmitting region 39.

That is, the display panel 1 according to some embodiments of the present disclosure is applied to transparent display. As described above, in the field of transparent display, in order to improve the transmittance, a polarizer is usually no longer provided, so that the polarizer cannot be used to block the flow of adhesive. However, after adopting the technical solution according to some embodiments of the present disclosure, the groove or the protrusion in the first film layer 5 can effectively block the adhesive. Therefore, there is no need to increase the width of the lower frame or reduce the coating distance of the adhesive, which can optimize the narrow frame or frameless design of the display panel 1, and improve the protection performance of the adhesive layer 7.

Based on the same inventive concept, the present disclosure further provides a method for manufacturing a display module, and in combination with FIG. 1 and FIG. 2, the manufacturing method includes forming the display panel 1. The display panel 1 includes a display region 2 and a first non-display region 3 located around the display region 2, and further includes a substrate 4 and a first film layer 5 located on a side of the substrate 4. The first film layer 5 includes an auxiliary sub-portion 6 that is located in the first non-display region 3, and the auxiliary sub-portion 6 includes a groove or a protrusion.

In combination with the above analysis, in the display module formed by adopting this manufacturing method, the auxiliary sub-portion 6 is located around the display region 2 and includes a groove or a protrusion. When a material having a certain fluidity is coated around the display region 2, when the material flows to the auxiliary sub-portion 6, the material fills in the groove or in the gap between the protrusions, thereby slowing the fluidity. In some embodiments of the present disclosure, when the display module includes the adhesive layer 7, and at least part of the adhesive layer 7 is located in the first non-display region 3, when coating the adhesive, the auxiliary sub-portion 6 may block the adhesive from flowing toward the display region 2, so as to prevent the adhesive from flowing to the display region 2 to affect normal optical display. In other words, since the auxiliary sub-portion 6 can be effectively used to prevent the adhesive from flowing to the display region 2, the coating thickness of the adhesive can be designed to be larger, so as to form a thick adhesive layer 7 and to improve the protection performance of the adhesive layer 7.

In some embodiments of the present disclosure, referring to FIG. 1 and FIG. 2, the display module further includes an adhesive layer 7, and the adhesive layer 7 is located on a side of the substrate 4 facing the first film layer 5 and at least located in the first non-display region 3.

Referring to FIG. 24, the first non-display region 3 of the display panel 1 includes two first edges 33 that are opposite. The arrangement direction of the two first edges 33 intersects with the arrangement direction of the display region 2 and the first non-display region 3, and the first edges 33 are arc-shaped edges.

The auxiliary sub-portion 6 includes a strip-shaped second sub-portion 32. The extending direction of the second sub-portion 32 intersects with the arrangement direction of the display region 2 and the first non-display region 3, and the first edge 33 exposes the end portion of the second sub-portion 32.

With reference to FIG. 25, the process of forming the display panel 1 and the adhesive layer 7 includes: a motherboard 34 is formed, the motherboard 34 includes a plurality of to-be-cut panels 35, the to-be-cut panel 35 includes a display panel 1, a blank region is formed between a first edge 33 of the display panel 1 and an edge of the to-be-cut panel 35, and an end portion of the second sub-portion 32 is located in the blank region; the motherboard 34 is cut to form the to-be-cut panels 35 that are independent of each other; the adhesive layer 7 is formed on a side of the to-be-cut panels 35; the to-be-cut panel 35 is cut at least along the first edge 33 to form the display panel 1.

In the above process, after coating the adhesive, when the adhesive flows to the second sub-portion 32, the adhesive fills in the second sub-portion 32, and then overflows to the blank regions on both sides along the extending direction of the second sub-portion 32, resulting in accumulation in the blank regions. After the adhesive is cured, the to-be-cut panel 35 is further cut along the edge of the display panel 1. The adhesive accumulated in the blank region is cut away along with the blank region, thereby preventing the accumulated adhesive from remaining in the display panel 1 and thus affecting the panel structure. Such technical solution is more suitable for panel structures with a thick adhesive layer 7. When the thick adhesive is coated, it can prevent the adhesive from accumulating inside the panel during the flowing process and affecting the panel structure.

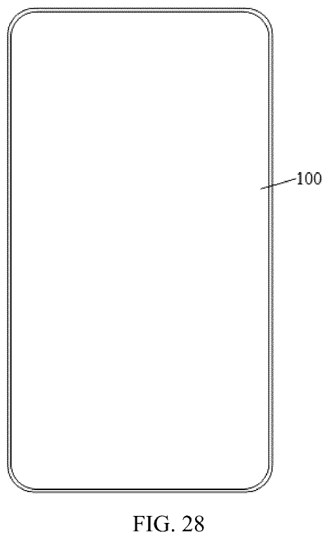

FIG. 28 is a schematic structural diagram of a display apparatus according to some embodiments of the present disclosure. Based on the same inventive concept, the present disclosure further provides a display apparatus, as shown in FIG. 28, the display apparatus includes the above display module 100. It is understandable that, the display apparatus shown in FIG. 28 is merely illustrative, and the display apparatus may be any electronic device having a display function, such as an in-vehicle display screen, a mobile phone, a tablet computer, a notebook computer, an electronic book, or a television, for example, any transparent electronic device having the display function.

The above description is only part of embodiments of the present disclosure and is not intended to limit the present disclosure, and any modifications, equivalent substitutions, improvements and the like made within the spirit and principle of the present disclosure should be included within the protection scope of the present disclosure.

As above, it should be noted that, the above-described embodiments are merely for illustrating the present disclosure but not intended to provide any limitation. Although the present disclosure has been described in detail with reference to the above-described embodiments, it should be understood that those skilled in the art may also modify the technical solutions described in the above embodiments or to equivalently replace some or all of the technical features therein, but these modifications or replacements do not cause the essence of corresponding technical solutions to depart from the scope of the present disclosure.

What is claimed is:

1. A display module, comprising a display panel, wherein the display panel comprises: a display region, a first non-display region located around the display region, a substrate and a first film layer located on a side of the substrate, the first film layer comprises an auxiliary sub-portion located in the first non-display region, and the auxiliary sub-portion comprises a groove or a protrusion.

2. The display module according to claim 1, further comprising:
an adhesive layer located on a side of the substrate facing the first film layer and at least located in the first non-display region.

3. The display module according to claim 2, wherein
at least part of the adhesive layer overlaps with the auxiliary sub-portion.

4. The display module according to claim 2, wherein
the display panel further comprises a bending region, at least part of the adhesive layer is located in the bending region, and the auxiliary sub-portion is located between the display region and the bending region.

5. The display module according to claim 2, wherein
the display panel further comprises a binding region located on a back side of the display panel; and
the display module further comprises a circuit board that is bonded and connected to the display panel in the binding region, and the adhesive layer at least covers a part of the circuit board located in the binding region.

6. The display module according to claim 1, wherein the display panel comprises:
an array layer comprising a plurality of metal layers, wherein some of the plurality of metal layers comprise a planarization layer on a side adjacent to and/or away from the substrate, and the first film layer comprises at least one planarization layer; and/or
a light-emitting device layer comprising an anode, a light-emitting layer, a pixel definition layer, and a cathode, wherein the pixel definition layer comprises a first opening, the first opening exposes the anode, the light-emitting layer is located in the first opening, and the first film layer comprises the pixel definition layer.

7. The display module according to claim 1, wherein
the first non-display region comprises a first region and a second region, and the first region is located between the display region and the second region, and the auxiliary sub-portion comprises a plurality of first sub-portions, and a density of the first sub-portions in the first region is different from a density of the first sub-portions in the second region, and/or a volume of the first sub-portions in the first region is different from a volume of the first sub-portions in the second region; or
wherein along a direction from the first non-display region toward the display region, a density of the first sub-portions gradually changes and/or a volume of the first sub-portions gradually changes.

8. The display module according to claim 1, wherein
the first non-display region comprises a first region and a second region, and the first region is located between the display region and the second region, and the auxiliary sub-portion comprises a plurality of first sub-portions;
an area of an orthographic projection of the first sub-portions in the first region is different from an area of an orthographic projection of the first sub-portions in the second region in a direction of a plane of the display module; and/or
in a direction perpendicular to the plane of the display module, a height of the first sub-portions in the first region is different from a height of the first sub-portions in the second region.

9. The display module according to claim 1, wherein
the auxiliary sub-portion comprises at least two sub-portion units arranged along a first direction, the first direction is parallel to an arrangement direction of the display region and the first non-display region, one of the at least two sub-portion units comprises a plurality of first sub-portions arranged along a second direction, and the second direction intersects with the first direction; and
for two adjacent sub-portion units of the at least two sub-portion units, along the first direction, a spacing between the first sub-portions in one of the two adjacent sub-portion units overlaps a spacing between the first sub-portions in the other one of the two adjacent sub-portion units.

10. The display module according to claim 9, wherein
in at least some of the at least two sub-portion units, along the second direction, a sum of a length of one first sub-portion of the plurality of first sub-portions and a distance between the one first sub-portion and its adjacent first sub-portion of the plurality of first sub-portions is greater than or equal to 10 μm and less than or equal to 30 μm.

11. The display module according to claim 1, wherein
the display panel comprises pixels; and
the auxiliary sub-portion comprises a plurality of first sub-portions, and in a direction perpendicular to a plane of the display module, a shape of a projection of the plurality of first sub-portions is same as a shape of the pixels.

12. The display module according to claim 1, wherein
the display panel comprises a light-shielding layer comprising a second opening; and
the auxiliary sub-portion comprises a plurality of first sub-portions, and in a direction perpendicular to a plane of the display module, a shape of a projection of the plurality of first sub-portions is the same as a shape of the second opening.

13. The display module according to claim 1, wherein
the auxiliary sub-portion comprises a strip-shaped second sub-portion, and an extending direction of the second sub-portion intersects with an arrangement direction of the display region and the first non-display region.

14. The display module according to claim 1, wherein
the auxiliary sub-portion comprises a plurality of first sub-portions arranged in an array and a strip-shaped second sub-portion, an extending direction of the second sub-portion intersects with an arrangement direction of the display region and the first non-display region, and the second sub-portion is located between at least some of the plurality of first sub-portions that are adjacent.

15. The display module according to claim 13, wherein
the first non-display region comprises two first edges that are opposite to each other, an arrangement direction of the two first edges intersects with the arrangement direction of the display region and the first non-display region, the first edges are arc-shaped edges, and the first edges expose an end portion of the second sub-portion.

16. The display module according to claim 1, wherein
along a direction perpendicular to a plane of the display module, a height of the groove or the protrusion is d1, where 1 μm≤d1≤10 μm; and/or
along an arrangement direction of the display region and the first non-display region, a length of the groove or the protrusion is d2, where 5 μm≤d2≤30 μm; and/or
along the arrangement direction of the display region and the first non-display region, a length of the auxiliary sub-portion is p, where 30 μm≤p≤150 μm.

17. The display module according to claim 1, wherein
the display panel further comprises a pixel circuit and a light-emitting element, the display region comprises a light-transmitting region and a non-light-transmitting region, and the pixel circuit and the light-emitting element are located in the non-light-transmitting region.

18. A method for manufacturing a display module, comprising: forming a display panel,
wherein the display panel comprises a display region, a first non-display region that is located around the display region, a substrate, and a first film layer that is located on a side of the substrate, the first film layer comprises an auxiliary sub-portion located in the first non-display region, and the auxiliary sub-portion comprises a groove or a protrusion.

19. The method according to claim 18, wherein
the display module further comprises an adhesive layer located on a side of the substrate facing the first film layer and at least located in the first non-display region;
the first non-display region of the display panel comprises two first edges that are opposite to each other, an arrangement direction of the two first edges intersects with an arrangement direction of the display region and the first non-display region, and the first edges are arc-shaped edges;
the auxiliary sub-portion comprises a strip-shaped second sub-portion, an extending direction of the second sub-portion intersects with the arrangement direction of the display region and the first non-display region, and the first edges expose an end portion of the second sub-portion; and
a process for forming the display panel and the adhesive layer comprises:
forming a motherboard, wherein the motherboard comprises a plurality of to-be-cut panels, one of the plurality of to-be-cut panels comprises the display panel, a blank region is formed between a first edge of the display panel and an edge of the to-be-cut panel, and an end portion of the second sub-portion is located in the blank region;
cutting the motherboard to form the to-be-cut panels that are independent of each other;
forming the adhesive layer on a side of the to-be-cut panel; and
cutting the to-be-cut panel at least along the first edge to form the display panel.

20. A display apparatus, comprising a display module, wherein the display module comprises a display panel, the display panel comprises: a display region, a first non-display region located around the display region, a substrate and a first film layer located on a side of the substrate, the first film layer comprises an auxiliary sub-portion located in the first non-display region, and the auxiliary sub-portion comprises a groove or a protrusion.
